(19) United States
(12) Patent Application Publication
(10) Pub. No.: US 2007/0006801 A1
(43) Pub. Date: Jan. 11, 2007

(54) USE OF SURFACTANTS TO CONTROL UNINTENTIONAL DOPANT IN SEMICONDUCTORS

(76) Inventors: Gerald B. Stringfellow, Salt Lake City, UT (US); Alexander D. Howard, Salt Lake City, UT (US); David C. Chapman, Stow, MA (US)

Correspondence Address: WORKMAN NYDEGGER;(F/K/A WORKMAN NYDEGGER & SEELEY), 60 EAST SOUTH TEMPLE, 1000 EAGLE GATE TOWER, SALT LAKE CITY, UT, 84111, US

(21) Appl. No.: 11/428,940

(22) Filed: Jul. 6, 2006

Related U.S. Application Data
(60) Provisional application No. 60/697,445, filed on Jul. 9, 2005.

(51) Int. Cl. C30B 23/00; C30B 25/00; C30B 28/12; C30B 28/14

(52) U.S. Cl. 117/104

(57) ABSTRACT

The use of surfactants that do not themselves act as dopants and are isoelectronic with either the group III or group V host atoms during OMVPE growth significantly reduces the incorporation of background impurities such as carbon, oxygen, sulfur and/or silicon. For example, the use of the surfactants Sb or Bi significantly reduces the incorporation of background impurities such as carbon, oxygen, sulfur and/or silicon during the OMVPE growth of III/V semiconductor materials, for example GaAs, GaInP, and GaP layers. As a result, an effective method for controlling the incorporation of impurity atoms is adding a minute amount of surfactant during OMVPE growth.

### CROSS-REFERENCE TO RELATED APPLICATIONS

This application claims the benefit of U.S. Provisional Patent Application No. 60/697,445, filed Jul. 9, 2005, which is incorporated herein by reference. This technology has Federal funding under the Department of Energy Grant No. DEFG0293ER45485.

### BACKGROUND OF THE INVENTION

1. The Field of the Invention

The present invention relates to the field of semiconductor devices. More particularly, the present invention relates to the use of surfactants to reduce impurities in semiconductor structures such as III/V semiconductors.

2. The Relevant Technology

It is vital to control the surface properties during epitaxial growth in III/V semiconductors in order to provide greater control of materials properties. This is of particular importance for organometallic vapor phase epitaxy (OMVPE) where the surface plays a vital role in determining many physical properties.

For example, the incorporation of dopants in III/V semiconductors has frequently presented problems, especially for high bandgap materials such as AlGaInP and AlGaInN. In AlGaInP, Mg and/or Zn acceptors are often unable to produce the high conductivity materials needed for light emitting diodes, lasers, solar cells, and other applications. The problem is even more serious in the AlGaInN alloys, where the inability to obtain sufficient p-type doping levels has retarded device development for decades. Three factors contribute to these problems: 1) acceptor solubility limits are small, especially in the high bandgap materials, 2) the acceptors may be compensated by H, especially for the high bandgap materials grown by organometallic vapor-phase epitaxy (OMVPE), and 3) the acceptor-hole binding energies may be large, causing the hole concentration to be much less than the acceptor concentration. These problems have necessitated modification of the OMVPE growth process in some way that leads to increased acceptor incorporation.

Additionally, unintentional impurities, particularly oxygen and carbon, have presented an obstacle for the OMVPE growth of III/V materials for decades. Carbon, from the pyrolysis of the organometallic precursors, is often present at high concentration. Oxygen has proven to increase non-radiative recombination and is difficult to eliminate, especially in Al containing materials. For GaInPN alloys, the high carbon doping levels contained in materials grown by OMVPE have hindered the development of high performance tandem solar cells. The longest minority carrier lifetimes are obtained only using growth conditions that minimize unintentional carbon and hydrogen contamination. Thus, a second major problem facing the OMVPE growth community is the development of simple and practical techniques for the reduction of contamination from undesirable impurities.

### BRIEF SUMMARY OF THE INVENTION

The present invention overcomes the foregoing problems of the prior art through the use of surfactants isoelectronic with either the group III or group V host atoms, that do not themselves act as dopants, during OMVPE growth. The surfactants reduce the incidence of contamination in semiconductor layers during OMVPE growth. More particularly, the use of surfactants such as Sb and Bi significantly reduces the incorporation of background impurities such as carbon, oxygen, sulfur and/or silicon during the OMVPE growth of III/V semiconductor materials, for example GaAs, GaInP, and GaP layers. As a result, according to the invention an effective method for controlling the incorporation of impurity atoms is adding a minute amount of surfactant during OMVPE growth.

Accordingly, a first example embodiment of the invention is a method of forming a doped layer in a semiconductor device. This method generally includes forming a layer of a group III material and a group V material in the presence of an acceptor dopant and a surfactant, whereby the surfactant causes the layer to have a substantially reduced impurity concentration and an increased concentration of acceptor dopant as compared to a similarly formed layer that is formed in the absence of the surfactant.

A second example embodiment of the invention is another method of forming a doped layer in a semiconductor device. This method generally includes: forming a layer of a group III material and a group V material in the presence of an acceptor dopant and a surfactant, whereby the acceptor dopant dopes the layer at a concentration greater than about 10²⁰ cm⁻³ and the surfactant causes the layer to have a substantially reduced impurity concentration of carbon, oxygen, silicon, or sulfur and an increased concentration of acceptor dopant as compared to a similarly formed layer that is formed in the absence of the surfactant.

Yet another example embodiment of the invention is a device formed by the methods of the invention, for example a P—N junction formed of a III/V semiconductor structure. The example P—N junction generally includes: a substrate comprising a group III material and a group V material; an n-type layer formed on the substrate, the n-type layer comprising a group III material, a group V material, and a majority of donor dopants; and a p-type layer formed on the n-type layer, the p-type layer comprising a group III material, a group V material, a majority of acceptor dopants, and a surfactant, wherein the surfactant causes the p-type layer to have a reduced presence of donor dopants and an increased concentration of the acceptor dopants.

These and other objects and features of the present invention will become more fully apparent from the following description and appended claims, or may be learned by the practice of the invention as set forth hereinafter.

### BRIEF DESCRIPTION OF THE DRAWINGS

To further clarify the advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 is a general illustration of a P—N junction structure according to one example embodiment of the invention;

FIG. 2 illustrates the sequence of layers formed according to the examples section of the patent application;

FIG. 3 is a graph illustrating the effects of the surfactant Bi according to an example embodiment of the invention;

FIG. 4 is another graph illustrating the effects of the surfactant Sb according to an example embodiment of the invention;

FIG. 5 is yet another graph illustrating the effects of the surfactant Bi according to an example embodiment of the invention;

FIG. 6 is a further graph illustrating the effects of the surfactant Sb according to an example embodiment of the invention;

FIG. 7 is another graph illustrating the effects of the surfactant Sb according to an example embodiment of the invention; and

FIG. 8 illustrates the effect of surfactants on surface activity according to the invention.

### DETAILED DESCRIPTION OF THE PREFERRED EMBODIMENTS

The present invention relates to the use of surfactants during OMVPE growth. The use of surfactants, such as Sb and Bi, significantly reduces the incorporation of background impurities such as carbon, oxygen, sulfur and/or silicon during the OMVPE growth of III/V semiconductor materials, for example GaAs, GaInP, and GaP layers. This decrease in residual impurity levels is beneficial for the production of materials for device applications.

Accordingly, an example method for reducing the incorporation of impurities during organometallic vapor-phase epitaxial (OMVPE) growth includes adding a surfactant isoelectronic with either the group III or group V host atoms during the OMVPE. The surfactant includes preferably Sb or Bi and a preferred acceptor dopant used during the OMVPE includes Zn.

As used herein, the term “surfactants” refers to substances that accumulate at the surface during growth and alter the surface properties. Such surfactants are substances with a low solubility (i.e. they are rejected from the solid) and a low vapor pressure (i.e. they do not rapidly evaporate). This results in a high surface concentration of the surfactant that in turn can profoundly affect the surface energy, surface diffusion, surface reconstruction, adatom attachment, and step structure. Preferred examples of surfactants according to the invention include Sb and Bi. Non limiting examples of Sb and Bi sources during OMVPE growth include triethylantimony (TESb) and trimethylbismuth (TMBi). The surfactants Sb and Bi are both group V elements which are rejected from incorporation into the solid due to their large size and can be used to change the physical and chemical processes occurring at the growing surface.

The use of these surfactants leads to significant decreases in carbon contamination during growth. By way of example, for GaP grown at 775° C., without surfactant the carbon contamination level reaches values of 2×10 cm⁻³. The addition of the surfactants Sb or Bi during OMVPE growth has resulted in a clear decrease in this carbon level by more than two orders of magnitude.

A marker that helps identify the mechanism for these effects is H incorporation. For example, both Sb and Bi surfactants give rise to increased concentrations of H in GaP and GaInP layers. In this case, the decrease in C incorporation corresponds to a sharp drop in the concentration of atomic H incorporated into the GaP layer.

The surfactants also result in a marked decrease in autodoping due to S and Si from the substrate. Although the invention is not bound by any particular theory, the reduction of C, S, and Si incorporation can be attributed to the increase in the H concentration on the surface due to Sb and Bi on the surface. The increased surface H is postulated to recombine with surface C, S, and Si species to form the stable, volatile hydrides CH₄, H₂S, and SiH₄. It is apparent that the judicious use of surfactants during OMVPE growth can be a powerful factor for the control of the surface processes leading to incorporation of dopants into the solid.

Additionally, in various embodiments of the invention the surfactants have the beneficial effect of increasing the desired dopant Zn incorporation. For example, for growth at 650° C., use of a surfactant can result in a Zn incorporation level of nearly 10²⁰ cm⁻³, the highest reported for GaP. H incorporation is seen to track Zn incorporation, with a Zn:H ratio ranging from 2:1 to 5:1. This effect is believed to be due to the increase in the H concentration on the surface caused by Sb or Bi. Thermodynamic effects favor the incorporation of neutral Zn—H defects at high Zn doping levels. Thus, the additional surface H facilitates Zn incorporation.

Thus, the incorporation of both dopants and background impurities during the OMVPE growth of GaAs, GaInP, and GaP has been significantly altered by the use of the surfactants Sb and Bi. Sb and Bi are isoelectronic with the group V host elements, and so produce no independent doping. The incorporation of Zn can be increased by an order of magnitude in GaP to a value of approximately 10²⁰ cm⁻³, the highest value reported to date.

More particularly regarding the theory behind the invention, although the invention is not tied to any particular theory, it is believed that the mechanism whereby the impurities are reduced is as follows. Due to weaker dimer bonds on the Sb or Bi covered surface, an increase of H on the surface to passivate dangling group V bonds is believed to occur. This gives rise to an observed increase of H incorporation into the solid. The increased H allows increased desportion of C, S, and Si from the surface by formation of volatile hydrides lead to decreased incorporation levels.

The effects of the surfactants Sb and Bi are most likely due to the change in surface reconstruction induced by the surfactants. It has been shown that both Sb and Bi produce marked changes in surface bonding, as evidenced by surface photo absorption (SPA) measurements. The change in surface bonding leads to an increase in atomic H adsorbed at the surface, based on the measured increase in H concentration incorporated into the solid, induced by addition of small quantities of either Sb or Bi to the system during growth. The mechanism has been postulated to be related to surface thermodynamics.

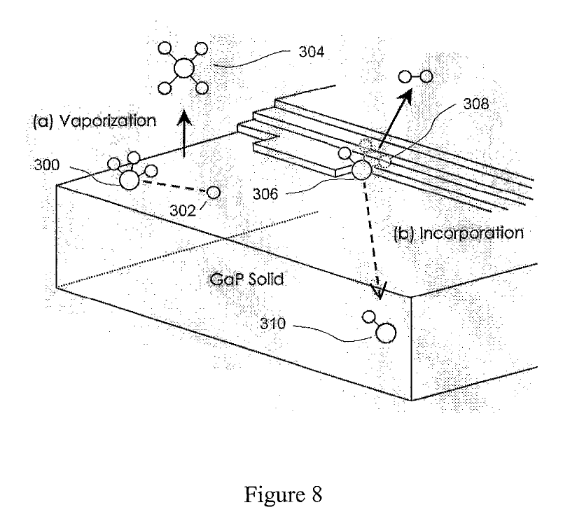

The behavior of carbon incorporation when Sb or Bi is added to the system would be a natural consequence of the additional levels of atomic H adsorbed at the surface. For OMVPE growth using trimethyl-III precursors, a significant concentration of methyl radicals on the surface during growth is to be expected. The surface CH₃ radicals 300, 306 have two possible fates, as indicated in the schematic diagram shown in FIG. 8. The CH₃ 300 can recombine with a surface H 302, creating CH₄ 304 which is rapidly desorbed. If the CH₃ radical 306 can also attach at a step site and lose one or more H ligands 308 before desorbing, it will result in the incorporation of C into the solid. The SIMS data suggest that the entity incorporated is actually the C—H complex 310, since the C:H ratio appears to be approximately unity. The Hall Effect data indicate that only a small fraction of the C—H complexes dissociate, since the free hole concentrations are consistently much lower than the C concentration in samples not doped with Zn. This suggests that the C—H is not dissociated during cool down. The H is bonded directly to the C in GaP in p-type material, resulting in effective neutralization of the carbon. Apparently, the energy necessary to dissociate the C—H complex is significantly larger than for the Zn—H pair. The effect of growth temperature is readily explained using this model. At lower temperatures, the probability that the C—H bond in CH₃ will break before desorption is much smaller than at the higher temperatures. Another factor that may play a role is that the CH₃ is more weakly bound to an Sb or Bi covered surface, since both the Sb—CH₃ and the Bi—CH₃ bonds are considerably weaker than the P—CH₃ bond.

The higher levels of adsorbed atomic H would also explain the reduction in S and Si produced by adding Sb or Bi to the surface. The increased concentration of surface hydrogen would lead to the formation of volatile SiH₄ and H₂S, both of which would be readily desorbed. This mechanism would also explain the reduction in oxygen due to Sb or Bi.

With reference now to FIG. 1, a non limiting example device 100 according to the invention is a surfactant enhanced P—N junction formed of a III/V semiconductor structure. The device 100 generally includes an n-type layer 104 formed on a substrate 102 with a p-type layer 106 formed thereover. As used herein, the term, “substrate” refers broadly to include materials upon which epitaxial layers are deposited. The layers deposited on the substrate may be doped either n- or p-type and contain the electrically and optically active elements of any device. In this example, the substrate 102 is a formed of a group III material and a group V material. The n-type layer 104 formed on the substrate 102, includes a group III material and a group V material and further includes a majority of donor dopants, for example C. The p-type layer 106 is formed of a group III material and a group V material, a majority of acceptor dopants, for example Zn, and a surfactant. The surfactant, for example Sb or Bi as described hereinabove, causes the p-type layer 106 to have a reduced presence of donor dopants and an increased concentration of the acceptor dopants. Because Sb and Bi are isoelectronic with the group V host elements, they produce no independent doping. Thus, the use of a surfactant results in a P—N junction having a high dopant concentration and a lower impurity concentration in the p-type layer 106. Of course, other device structures can be formed to take advantage of the methods of the invention and will be apparent to those skilled in the art in view of the disclosure herein.

The following examples are given to illustrate the present invention, and are not intended to limit the scope of the invention.

### EXAMPLES

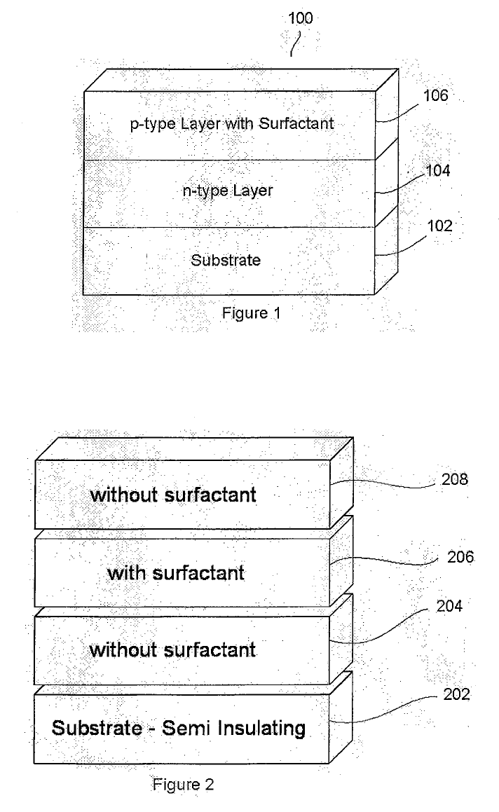

With reference now to FIG. 2, for Examples 1-5 four-layer structures were formed under different process conditions to evaluate the effects of different materials and process parameters in using surfactants to reduce the incorporation of undesired impurities. In the examples, the formed test structures include three sequential layers 204, 206, 208 formed over a substrate 202. The layers, in order over substrate 202, include a first layer 202 formed without a surfactant, a second layer 204 formed with a surfactant, and a third layer 206 formed without a surfactant. The layers are GaP crystals grown with or without surfactants Sb and Bi and grown by OMVPE in a horizontal, infrared heated, atmospheric pressure reactor on singular semi-insulating GaP substrates 202. Trimethylgallium (TMGa), tertiarybutylphosphine (TBP), dimethylzinc (DMZn), trimethylbismuth (TMBi), and trimethylantimony (TMSb) were used as the organometallic precursors.

The carrier gas was Pd-diffused hydrogen. The growth temperatures were 650° C. and 775° C. for GaP and V/III ratios were 60 and 24 respectively. Throughout the experiment a constant growth rate of 1 atm/h was maintained. The Zn/III was varied to account for the change in distribution coefficient at different temperatures. At 650° C. the Zn/III was held constant at 0.15, while at 775° C. the Zn/III was changed from 6.05 to 0.69.

GaAs:Zn samples were grown on GaAs semi-insulating substrates using Bi as a surfactant similar to above. The organometallic sources remained the same with the addition of arsine and the growth temperatures were 560° C. and 680° C.

Single layer samples were grown for Hall Effect measurements to determine electrically active carriers. These samples were 0.75 μm thick, which was verified using calibrated growth rates from SIMS and profilometry. Samples were grown with either Zn alone or Zn and surfactant. The measurements were performed using the Van der Pauw method at room temperature using an 1100 Gauss electromagnet. Ohmic contacts were made to the samples using an In—Zn alloy annealed under N2 at 350° C.

Secondary Ion Mass Spectroscopy (SIMS) depth profiles were measured on GaP three layer structures where the surfactant was only present during growth of the middle layer. Growth was stopped between layers for 30 seconds to adjust flows for the introduction and removal of the surfactant and to allow the flows to equalize. In addition, SIMS was measured on single layer GaAs samples to determine the correlation between Zn and H. Applied Microanalysis Laboratory performed the measurements using a Cameca ims-3f system.

The examples confirmed that the addition of surfactant Sb (TESb) or Bi (TMBi) leads to a decreased incorporation of C, S, and Si into GaP layers grown by OMVPE at 650° C. and 775° C.

### Example 1

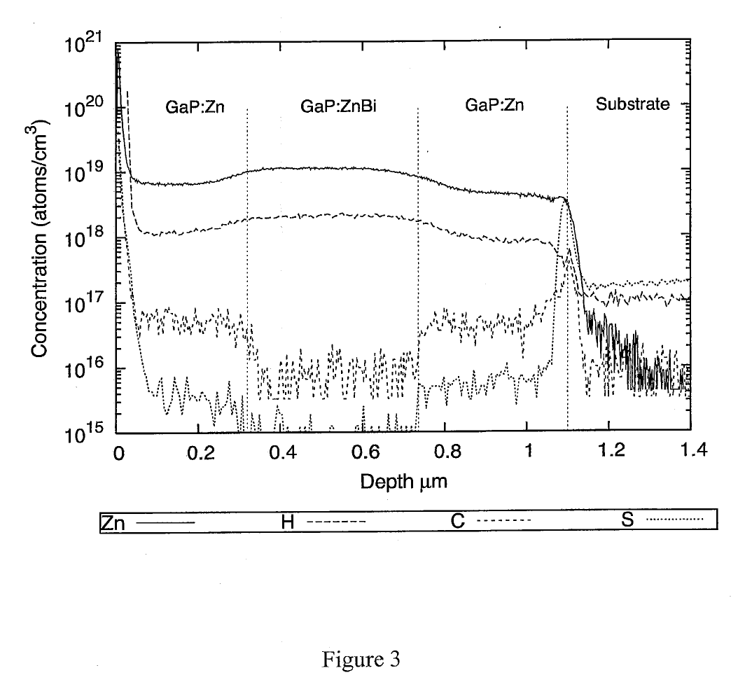

FIG. 3 shows the SIMS profile of a three layer structure GaP based structure, grown at 650° C. using a Zn/III ratio in the input vapor of 0.15, consisting of sequential 0.25 micron layers all grown with the addition of Zn, but with Bi added only during growth of the middle layer. The SIMS profile of FIG. 3 shows an abrupt decrease in the carbon contamination level in the layer grown with Bi (labeled GaP:ZnBi). The carbon doping level in the GaP grown at 650° C. without Bi is seen to be approximately 5×10¹⁶ cm⁻³. The use of the surfactant Bi, however, led to a decrease in the carbon concentration to generally less than 10¹⁶ cm⁻³. The concentration of sulfur, in the layer from autodoping from the substrate, is also decreased by the presence of Bi.

It is also worth noting that the presence of Bi on the surface during OMVPE growth led to an increase in Zn incorporation by a factor of approximately 3. In FIG. 3, the H concentration is seen to follow the Zn incorporation, i.e., H incorporation also increases by approximately 3× in the layer grown with Bi. Strikingly, the ratio of Zn/H remains virtually constant with a value of approximately 5:1 in the layers grown both with and without surfactant. In the graded transition regions, where Zn has apparently diffused from the middle layer (grown with Bi) to the surrounding layers (grown without Bi). A similar amount of Zn diffusion is observed in the substrate.

### Example 2

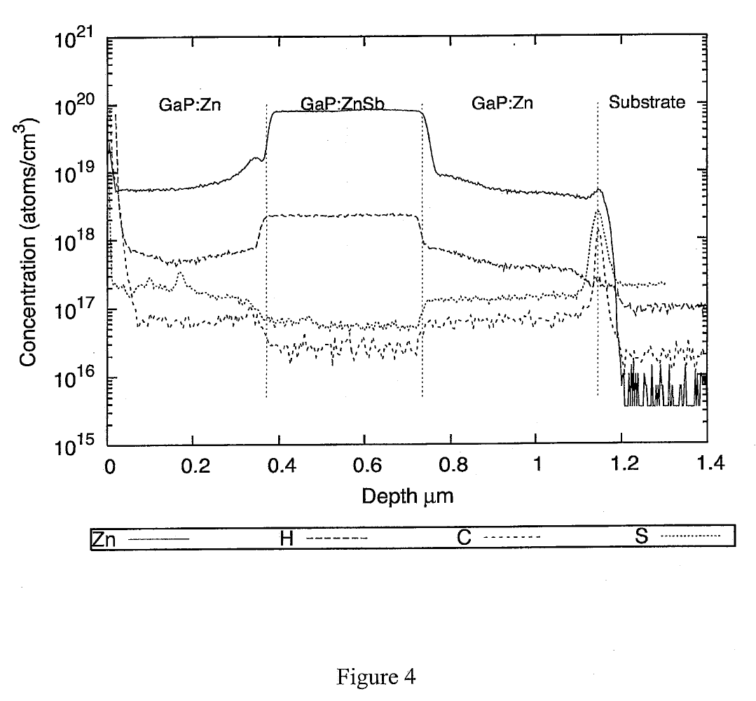

FIG. 4 shows the SIMS profile of a three layer structure GaP based structure, grown at 650° C., showing that the use of Sb also results in a significant decrease in the concentration of both C and S. Though the reduction in the concentration of C and S is not as striking as with Bi, it is still evident.

More striking in this example is the rise in Zn incorporation in GaP grown at 650° C. As expected, the Zn doping level in the layers grown without Sb is the same as for similar layers shown in FIG. 3, approximately 7×10¹⁸ cm⁻³. However, with Sb present during growth, the Zn incorporation is increased by more than an order of magnitude to a value of 9×10¹⁹ cm⁻³. This is the highest p-type doping level reported for GaP. Again, as was the case in layers grown with Bi, the surfactant Sb causes a nearly parallel increase in the H incorporation into the solid. However, the Zn:H ratio in the layer grown with Sb present is approximately 45:1, much larger than for Bi. The larger Zn:H ratio in the layers grown without Sb is, surprisingly, also somewhat higher than the ratio observed in Bi.

### Examples 3-4

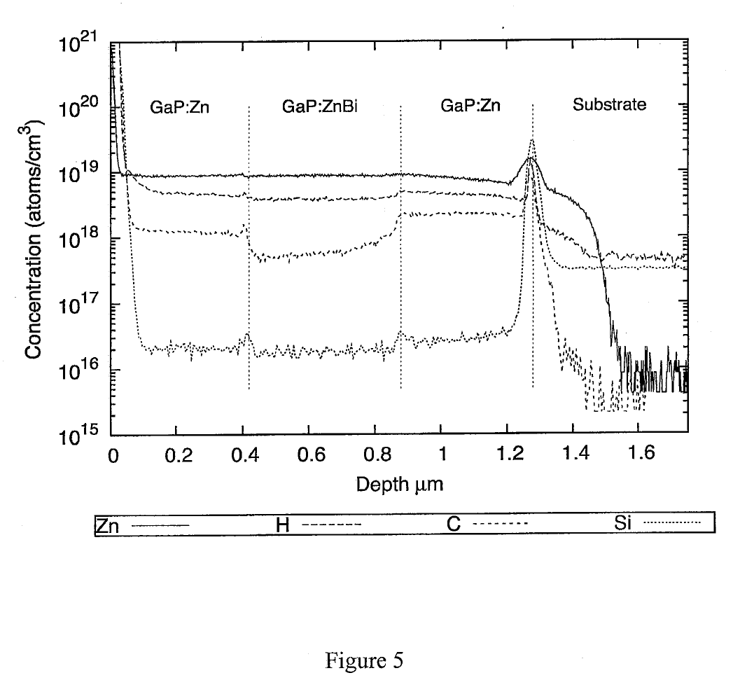

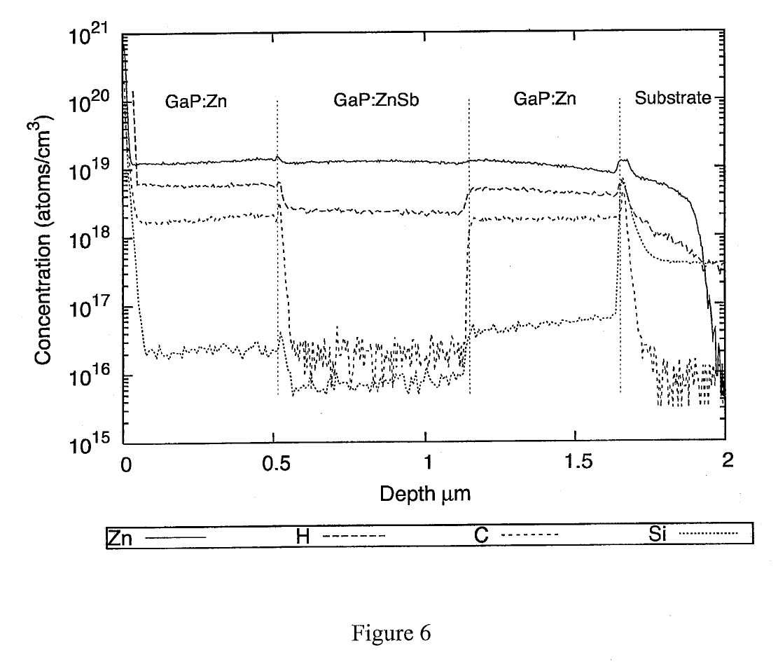

Similar experiments to those of Examples 1 and 2 were performed at the much higher temperature of 775° C. The concentration of DMZn in the vapor was increased significantly to compensate for the increased rate of Zn desorption from the surface during growth. Thus, a value of Zn/III of 6.05 was used for the samples shown in FIGS. 5 and 6.

FIG. 5 shows the effects of Bi on the SIMS profile of a 3 layer GaP structure grown at 775° C. In the layers grown without Bi, a high C contamination level of 2×10¹⁸ cm⁻³ was observed. Again, as for the GaP grown at lower temperatures, the presence of Bi resulted in a significant decrease in the C level by more than a factor of 2.

A slight reduction in the Si doping level was also observed. No S incorporation into the GaP epitaxial layers was observed for growth at these higher temperatures. Generally, Si doping is known to increase while S doping to decrease as the growth temperature is increased.

Surprisingly, however, the effect of Bi on Zn concentration appears to be insignificant at 775° C. In the layers grown both with and without Bi, the Zn:H ratio is observed to be approximately 2:1, considerably lower than the values in the GaP layers grown at 650° C.

The effect of Sb during growth at 775° C. is shown in FIG. 6. The C concentration was observed to drop from approximately 2×10¹⁸ cm⁻³ in the layers grown without surfactant to a value of <2×10¹⁶ cm⁻³, most likely the SIMS detection limit, in the layer grown with Sb present. The data in FIG. 6 also show a clear decrease in Si doping for the layer grown with Sb.

As with Bi, the surfactant Sb appeared to have very little effect on the Zn incorporation. The H incorporation also decreased when Sb is added to the system during growth. This can be explained by the combination of Zn and C doping. Clearly, H incorporation is larger in the layers highly doped with C, which accounts for the drop in H in the layer grown with Sb. This layer, which contains little C, demonstrates a Zn:H ratio of approximately 5:1, a value similar to those reported above for layers grown at 650° C. The values of the Zn:H ratios as observed in these experiments are summarized in Table II. The increased H in the layers grown without Sb indicates a C:H ratio of approximately unity, much larger than the Zn:H ratios.

### Example 5

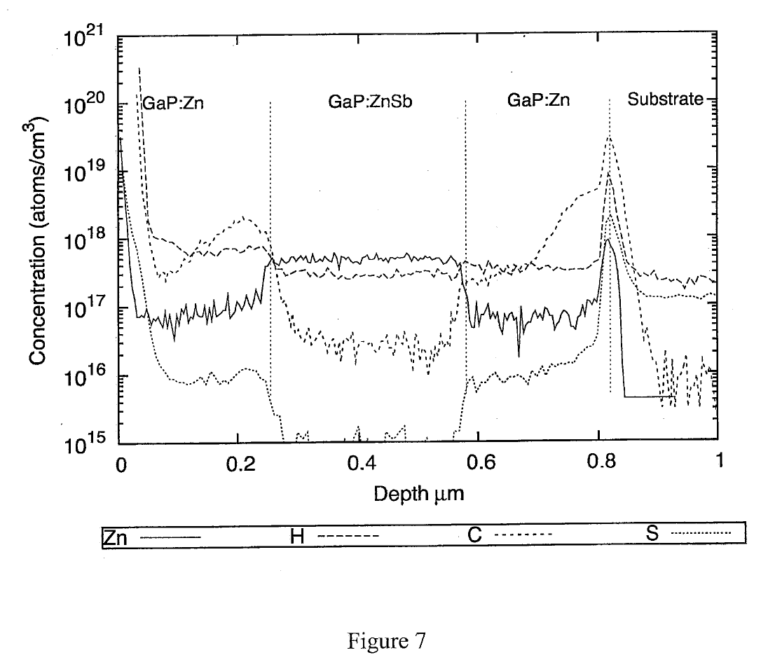

To more clearly study the Zn, C and H incorporation at 775° C., a three layer structure was grown with decreased Zn/III ratio in the vapor. As demonstrated in FIG. 7, this decreased ratio results in a Zn concentration in the layers grown without Sb of approximately 8×10¹⁶ cm⁻³, more than 2 orders of magnitude lower than for the data shown in FIG. 6. Marked reductions in C and Si concentrations due to the presence of Sb were noted under these conditions.

In addition, the increase in Zn doping by a factor of 5 produced by the addition of surfactant Sb to the system reappears. This supports the assertion that the flat Zn doping in FIGS. 5 and 6 is due to Zn diffusion. As the temperature decreases the Zn diffusion length is reduced, as clearly observed at the substrate/epitaxial layer interface. This significant decrease in Zn diffusion occurs because the diffusion coefficient is strongly dependent on Zn concentration due to the interstitial diffusion mechanism. This suggests that Zn diffusion between the layers in FIGS. 5 and 6 is larger than between the first layer and the substrate, due to the increased Zn incorporation induced by the Sb and Bi.

The SIMS data from FIG. 7 are somewhat unclear, but it appears that the C:H ratio in the layers grown without surfactant is greater than or equal to 1 and the Zn:H ratio in the layer grown with Sb present is approximately 2.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method of forming a doped layer in a semiconductor device, the method comprising forming a layer of a group III material and a group V material in the presence of an acceptor dopant and a surfactant, whereby the surfactant causes the layer to have a substantially reduced impurity concentration and an increased concentration of acceptor dopant as compared to a similarly formed layer that is formed in the absence of the surfactant.

2. A method as defined in claim 1, wherein the surfactant comprises at least one of Si and Bi.

3. A method as defined in claim 2, wherein a source of the surfactant comprises trimethylbismuth (TMBi).

4. A method as defined in claim 2, wherein a source of the surfactant comprises trimethylantimony (TMSb).

5. A method as defined in claim 1, wherein the acceptor dopants comprise Zn.

6. A method as defined in claim 1, wherein the impurity comprises carbon.

7. A method as defined in claim 1, wherein the impurity comprises at least one of Si, S, and O.

8. A method of forming a doped layer in a semiconductor device, the method comprising forming a layer of a group III material and a group V material in the presence of an acceptor dopant and a surfactant, whereby the acceptor dopant dopes the layer at a concentration greater than about 10²⁰ cm⁻³ and the surfactant causes the layer to have a substantially reduced impurity concentration of carbon, oxygen, silicon, or sulfur and an increased concentration of acceptor dopant as compared to a similarly formed layer that is formed in the absence of the surfactant.

9. A method as defined in claim 8, wherein the surfactant comprises at least one of Sb and Bi.

10. A method as defined in claim 9, wherein a source of the surfactant comprises trimethylbismuth (TMBi).

11. A method as defined in claim 9, wherein a source of the surfactant comprises trimethylantimony (TESb).

12. A method as defined in claim 8, wherein the acceptor dopants comprise Zn.

13. A method as defined in claim 8, wherein the impurities comprise carbon.

14. A method as defined in claim 8, wherein the impurities comprise at least one of Si, S, and O.

15. A P—N junction formed of a III/V semiconductor structure, comprising:
a substrate comprising a group III material and a group V material;
an n-type layer formed on the substrate, the n-type layer comprising a group III material, a group V material, and a majority of donor dopants; and
a p-type layer formed on the n-type layer, the p-type layer comprising a group III material, a group V material, a majority of acceptor dopants, and a surfactant.

16. A junction as defined in claim 15, wherein the surfactant causes the p-type layer to have a reduced presence of the donor dopants and an increased concentration of the acceptor dopants.

17. A junction as defined in claim 15, wherein the surfactant comprises at least one of Sb and Bi.

18. A junction as defined in claim 15, wherein a source of the surfactant comprises trimethylbismuth (TMBi).

19. A junction as defined in claim 15, wherein a source of the surfactant comprises trimethylantimony (TESb).

20. A junction as defined in claim 15, wherein the acceptor dopants comprise Zn.

21. A junction as defined in claim 15, wherein the donor dopants comprise C.

22. A junction as defined in claim 15, wherein the impurities comprise at least one of Si, S, and O.
